(19) United States
(12) Patent Application Publication
(10) Pub. No.: US 2019/0181009 A1
(43) Pub. Date: Jun. 13, 2019

(54) APPARATUS FOR ANNEALING A LAYER OF SEMICONDUCTOR MATERIAL, A METHOD OF ANNEALING A LAYER OF SEMICONDUCTOR MATERIAL, AND A FLAT PANEL DISPLAY

(71) Applicant: M-SOLV LIMITED, Oxford, Oxfordshire (GB)

(72) Inventors: Philip Thomas RUMSBY, Bladon, Oxfordshire (GB); David Thomas Edmund MYLES, Kidlington, Oxfordshire (GB)

(73) Assignee: M-SOLV LIMITED, Oxford, Oxfordshire (GB)

(21) Appl. No.: 16/327,186

(22) PCT Filed: Aug. 16, 2017
(86) PCT No.: PCT/GB2017/052423

§ 371 Date: Feb. 21, 2019

(30) Foreign Application Priority Data
Aug. 22, 2016 (GB) 1614342.2
Jan. 17, 2017 (GB) 1700800.4

(51) Int. Cl. H01L 21/263; H01L 21/428; H01L 21/268; H01L 21/67; H01L 27/12

(52) U.S. Cl. CPC H01L 21/2636; H01L 21/428; H01L 27/1285; H01L 21/67115; H01L 21/268

(57) ABSTRACT

Methods and apparatus for annealing a layer of semiconductor material, particularly amorphous silicon or IGZO, are provided. In one arrangement, an apparatus comprises a laser source that generates a laser beam. A beam scanning arrangement scans the laser beam, or a plurality of sub-beams generated by the laser beam, relative to the layer of semiconductor material in such a way as to selectively irradiate a plurality of regions of the layer of semiconductor material and thereby generate a corresponding plurality of regions of annealed semiconductor material, particularly polysilicon or annealed IGZO. Each of the regions of annealed semiconductor material is separated from all of the other regions of annealed semiconductor material.

The invention relates to apparatus and methods for efficiently annealing a semiconductor material, for example to convert amorphous silicon to polysilicon by annealing or to convert IGZO to annealed IGZO, particularly for manufacturing the thin film transistors required in large flat panel displays (FPDs) based for example on liquid crystal (LC) or organic light-emitting diode (OLED) materials

To provide polysilicon for the electronics (e.g. TFTs) in each pixel of an LC display (LCD) or OLED display (or other FPD), it is known to provide a layer of amorphous silicon and use annealing to convert the amorphous silicon to polysilicon. In one process, as depicted in FIG. 1, a long, narrow line laser beam 4 is scanned slowly over a layer of amorphous silicon on a substrate 2 to provide a single, continuous region of polysilicon. The line laser beam may be formed using a UV (e.g. 308 nm) excimer laser or a multi-mode green DPSS laser, for example. The line laser beam may typically be up to about 750 mm in length and about 30 microns wide. The speed of the scanning and the pulse repetition rate are controlled so that all of the irradiated region receives substantially the same radiation dose and is converted reliably to polysilicon. By converting all of the amorphous silicon to polysilicon in the continuous region, polysilicon will be available in sub-regions 6 where TFTs need to be provided, for driving individual pixels (and colours within pixels) of the display.

Similar processing may be required for annealing alternative semiconductor materials such as indium gallium zinc oxide (IGZO) to improve their properties, for example to improve spatial uniformity of their electrical properties and/or carrier mobility.

As displays become larger it is becoming increasingly difficult to perform the above processing sufficiently quickly and in a cost-effective manner. It is difficult for example to increase the length of individual line laser beams and provide the required increase in laser pulse energy.

It is an object of the invention to provide improved methods and apparatus for providing regions of annealed semiconductor material, particularly for manufacturing large FPDs.

According to an aspect of the invention, there is provided an apparatus for annealing a layer of semiconductor material, comprising: a laser source configured to generate a laser beam; and a beam scanning arrangement configured to scan the laser beam, or a plurality of sub-beams generated from the laser beam, relative to the layer of semiconductor material in such a way as to selectively irradiate a plurality of regions of the layer of semiconductor material and thereby generate a corresponding plurality of regions of annealed semiconductor material by annealing, wherein each of the regions of annealed semiconductor material is separated from all of the other regions of annealed semiconductor material.

The semiconductor material to be annealed may comprise amorphous silicon or IGZO for example. The annealed semiconductor material may comprise polysilicon or an annealed form of IGZO (e.g. a form of IGZO in which electrical properties have been made more uniform by annealing and/or in which carrier mobility has been improved by annealing).

In an embodiment, there is provided an apparatus for annealing a layer of amorphous silicon, comprising: a laser source configured to generate a laser beam; and a beam scanning arrangement configured to scan the laser beam, or a plurality of sub-beams generated from the laser beam, relative to the layer of amorphous silicon in such a way as to selectively irradiate a plurality of regions of the layer of amorphous silicon and thereby generate a corresponding plurality of regions of polysilicon by annealing, wherein each of the regions of polysilicon is separated from all of the other regions of polysilicon.

By providing an apparatus capable of selectively irradiating a plurality of separated regions, it is possible to perform the annealing of the semiconductor material (e.g. amorphous silicon or IGZO) using a much lower total energy. The proportion of the original layer of semiconductor material can be much closer to the proportion that is actually needed to support the electronic devices (e.g. TFTs) to be fabricated. For example, in the case of an LCD or OLED display, the proportion of the total area of the display in which TFTs may need to be formed is typically of the order of 3% of the total area. If a line laser beam were used to provide the polysilicon, as in the prior art, substantially 100% of the total area would be annealed. The selective irradiation of the invention would typically require irradiation of a proportion much nearer to the 3%, typically in the region of about 10% (to provide a safety margin around each of the TFT regions). This approach reduces power requirements, increases processing speed and reduces processing cost

In an embodiment, the laser beam is split into a plurality of sub-beams. The plurality of sub-beams are scanned over the layer of semiconductor material (e.g. amorphous silicon or IGZO). This approach has been found to provide a particularly efficient way of providing the selective irradiation. The technique can be implemented at low cost and provides the basis for rapidly processing large areas of semiconductor material. Multiple lasers and corresponding beam splitters can be used to process particularly large areas or multiple areas in parallel.

In an embodiment, the laser beam is a pulsed laser beam and the beam scanning arrangement is configured so that each sub-beam of the plurality of sub-beams is scanned relative to the layer of semiconductor material in such a way that successive pulses of the sub-beam irradiate different respective ones of the plurality of regions of the layer of semiconductor material to be irradiated. This approach provides a degree of flexibility in how radiation dose is applied to each region that is not available in the prior art. For example, in prior art arrangements using a line laser beam, the intensity profile within the line laser beam parallel to the direction of scanning of the line laser beam will generally be Gaussian. This means that each region being irradiated by the line laser beam will receive pulses that increase and then decrease in intensity and no other arrangement will be easily possible. Varying the pulse intensity in this manner will not be optimal for annealing the semiconductor material, further increasing the total amount of radiation that needs to be applied using the prior art approach relative to the invention.

In one particular embodiment, the energy per pulse received by each of the plurality of regions is substantially the same for each pulse. In an alternative embodiment, the energy per pulse received by each of the plurality of regions increases progressively for each pulse received by the region. The efficiency of the annealing process is thereby improved further relative to the Gaussian variation provided by prior art arrangements.

According to an alternative aspect, there is provided a method of annealing a layer of semiconductor material, comprising: generating a laser beam; and scanning the laser beam, or a plurality of sub-beams generated from the laser beam, over the layer of semiconductor material in such a way as to selectively irradiate a plurality of regions of the layer of semiconductor material and thereby generate a corresponding plurality of regions of annealed semiconductor material, wherein each of the regions of annealed semiconductor material is separated from all of the other regions of annealed semiconductor material.

According to an embodiment, there is provided a method of annealing a layer of amorphous silicon, comprising: generating a laser beam; and scanning the laser beam, or a plurality of sub-beams generated from the laser beam, over the layer of amorphous silicon in such a way as to selectively irradiate a plurality of regions of the layer of amorphous silicon and thereby generate a corresponding plurality of regions of polysilicon, wherein each of the regions of polysilicon is separated from all of the other regions of polysilicon.

The method may be used as part of a method of manufacturing a flat panel display, particularly an LCD or OLED display.

The invention will now be further described, by way of example, with reference to the accompanying drawings, in which:

FIG. 1 depicts scanning of a line laser beam over a layer of semiconductor material to anneal the semiconductor material;

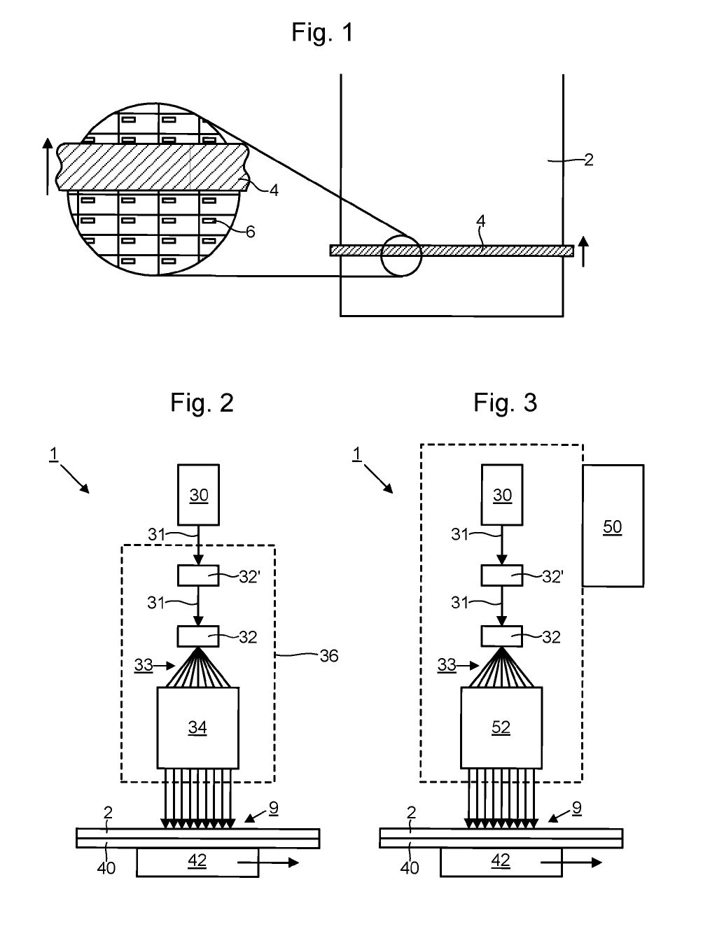

FIG. 2 depicts an apparatus for annealing a layer of semiconductor material comprising a beam scanner;

FIG. 3 depicts an alternative apparatus for annealing a layer of semiconductor material without a beam scanner;

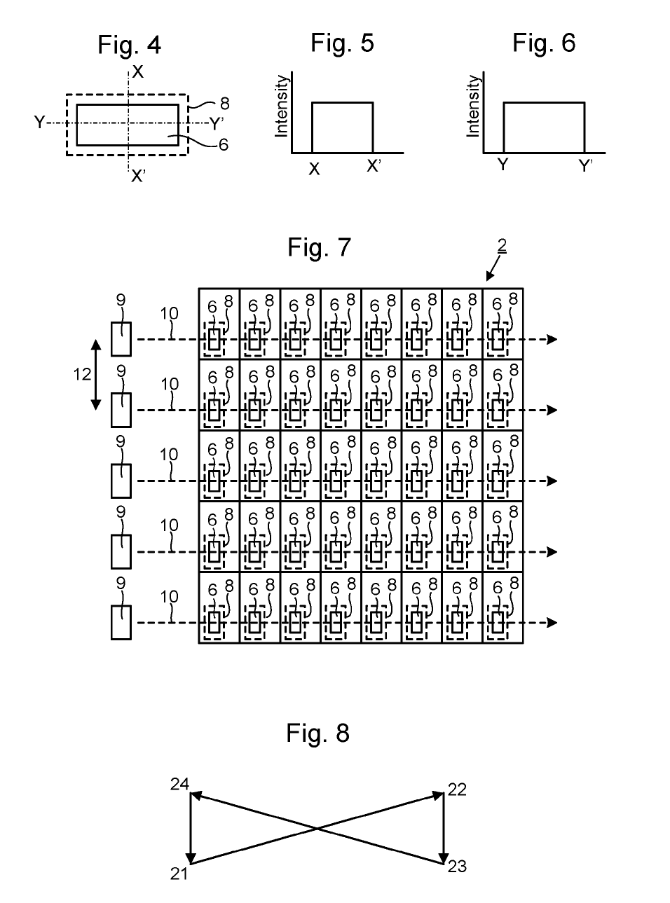

FIG. 4 depicts an individual irradiated region relative to a TFT region;

FIG. 5 depicts an intensity profile along line X-X′ in the irradiated region of FIG. 4;

FIG. 6 depicts an intensity profile along line Y-Y′ in the irradiated region of FIG. 4;

FIG. 7 depicts scanning of a plurality of sub-beams over a layer of semiconductor material to selectively irradiate a plurality of regions of the semiconductor material;

FIG. 8 depicts a bow-tie type scanning pattern;

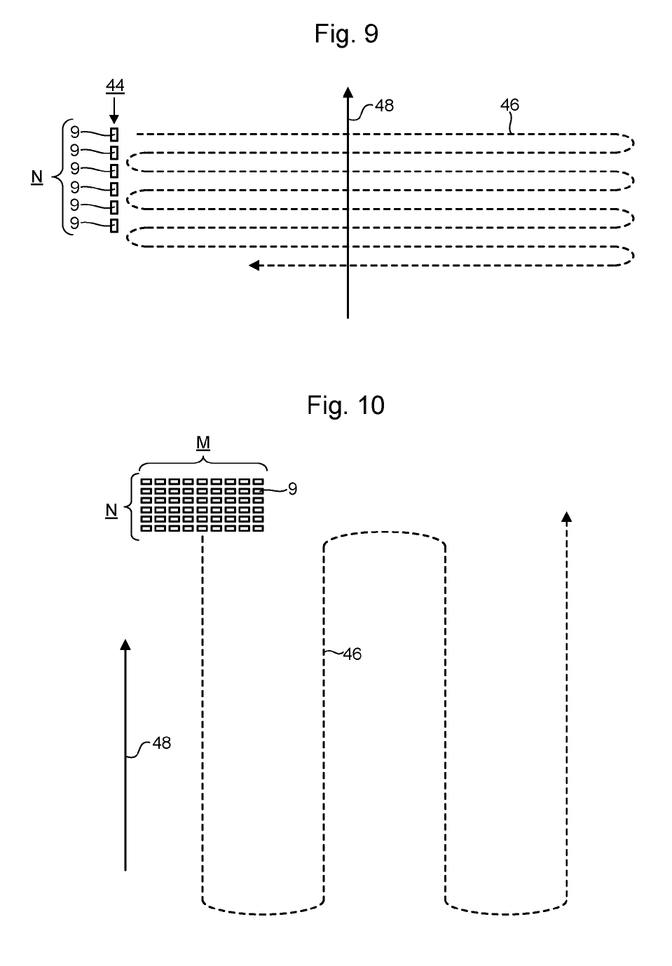

FIG. 9 depicts a first embodiment of raster scanning of a plurality of sub-beams over a layer of semiconductor material;

FIG. 10 depicts a second embodiment of raster scanning of a plurality of sub-beams over a layer of semiconductor material;

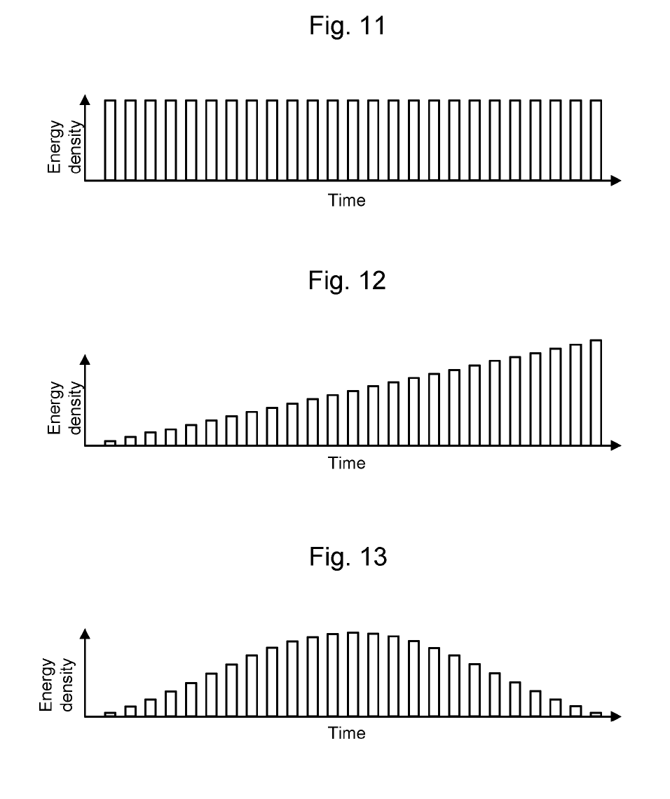

FIG. 11 is a bar chart showing an example variation of energy density received at a region as a function of time (corresponding to an intensity profile across a plurality of sub-beams);

FIG. 12 is a bar chart showing a further example variation of energy density received at a region as a function of time (corresponding to an intensity profile across a plurality of sub-beams);

FIG. 13 is a bar chart showing a further example variation of energy density received at a region as a function of time (corresponding to an intensity profile across a plurality of sub-beams); and

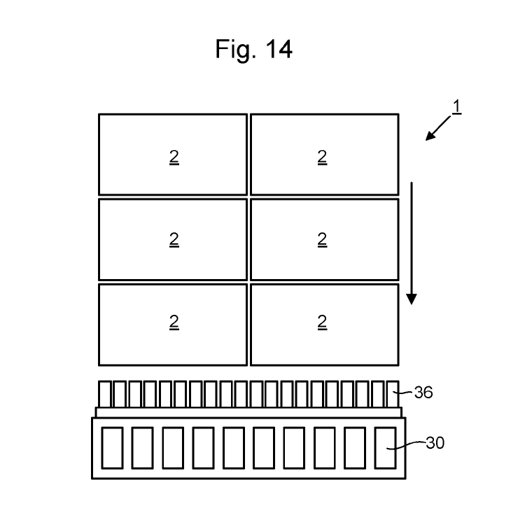

FIG. 14 depicts a gantry comprising multiple laser systems for processing plural substrates in parallel.

As mentioned in the introductory part of the description, as displays get larger it is becoming increasingly difficult efficiently to provide polysilicon (or other annealed semiconductor material) for the TFTs for each pixel. Consider for example typical requirements for a 70 inch 8K resolution display. Such a display will have overall dimensions of 1550×872 mm. 7680 pixels would be required along the length. 4320 pixels would be required along the width. Each pixel would have a width of about 67 microns and a height of about 202 microns. The number of TFT units for such a display would be 23040 along the length (one TFT unit being required for each of the three colours) and 4320 along the width. Nearly 100 million TFT units are therefore required.

In the prior art substantially all of the 1550×872 mm display area would need to be subjected to annealing radiation to provide the annealed semiconductor material (e.g. polysilicon or annealed IGZO). The embodiments described below greatly reduce the total amount of annealing that is carried out while still providing all of the annealed semiconductor material (e.g. polysilicon or annealed IGZO) required for the nearly 100 millions TFTs.

In an embodiment, examples of which are depicted in FIGS. 2 and 3, there is provided an apparatus 1 for annealing a layer 2 of semiconductor material (e.g. amorphous silicon or IGZO). The layer 2 of semiconductor material (e.g. amorphous silicon or IGZO) may be conveyed by a layer transport device 42. The layer 2 of semiconductor material (e.g. amorphous silicon or IGZO) may be supported on a substrate 40. The substrate 40 may in turn be supported (and conveyed) by the layer transport device 42. The layer transport device 42 may comprise a movable table supporting and/or gripping the substrate 40.

The apparatus 1 comprises a laser source 30 that generates a laser beam 31. The laser source 30 may be a pulsed laser source 30. Any laser source that is capable of annealing the semiconductor material (e.g. amorphous silicon or IGZO) can be used. Details of the laser source may vary according to the particular characteristics of the semiconductor material to be annealed. In an embodiment, the laser source 30 is a low M² high repetition rate DPSS laser. In an embodiment, the laser source 30 is a UV laser source generating pulses of radiation at about 355 nm (particularly suitable for annealing amorphous silicon). In an alternative embodiment, the laser source 30 is a green laser source generating pulses of radiation at about 532 nm (also suitable for annealing amorphous silicon). In an alternative embodiment, the laser source 30 is a DUV laser source generating pulses at about 266 nm (particularly suitable for annealing IGZO). The laser source 30 may comprise a multi-mode high power laser, optionally a high M² low repetition rate DPSS laser. This latter embodiment may be particularly applicable where a two-dimensional array of beam spots are generated, due to the higher power requirements. An example of such an arrangement is described below with reference to FIG. 10. The laser source 30 may comprise a Q switched laser source. In an embodiment, the laser source 30 is configured to provide pulses having pulse lengths of 200 ns or less, optionally 150 ns or less, optionally 100 ns or less.

In the embodiments shown in FIGS. 2 and 3, an optical element 32 (e.g. a diffractive optical element, DOE) generates a plurality of sub-beams 33 by splitting the laser beam 31.

A beam scanning arrangement is provided that scans the laser beam 31, or a plurality of sub-beams 33 generated from the laser beam 31 (as in the embodiments of FIGS. 2 and 3), relative to (over) the layer 2 of semiconductor material (e.g. amorphous silicon or IGZO) to be annealed. The scanning is performed in such a way as to selectively irradiate a plurality of regions of the layer 2 of semiconductor material (e.g. amorphous silicon or IGZO). A corresponding plurality of regions of annealed semiconductor material (e.g. polysilicon or annealed IGZO) are produced by the irradiation. Each region of annealed semiconductor material is separated from every other region of annealed semiconductor material.

In one embodiment, the semiconductor material comprises, consists essentially of, or consists of, amorphous silicon and the irradiation is such as to anneal the amorphous silicon to form polysilicon.

In an alternative embodiment, the semiconductor material comprises, consists essentially of, or consist of, IGZO and the irradiation is such as to anneal the IGZO to form annealed IGZO. In an embodiment, the annealed IGZO has significantly different electrical properties than the IGZO prior to the annealing, including for example higher spatial uniformity of electrical properties and/or increased carrier mobility.

In an embodiment, an example of which is depicted in FIG. 2, the beam scanning arrangement comprises a beam scanner 34. The beam scanner 34 provides movement relative to the laser source 30 of one or more beam spots 9 generated by the laser beam 31 or by the plurality of sub-beams 33, thereby at least partially performing the scanning of the laser beam 31 or plurality of sub-beams 33 relative to the layer 2 of semiconductor material (e.g. amorphous silicon or IGZO). The controlled movement of the one or more beam spots 9 may be achieved for example by controlled deflection or steering of the laser beam 31 or sub-beams 33, for example using moving mirrors, scanning refractive optics, acousto-optic deflectors, or electro-optic deflectors, or any other technique known in the art of beam scanners. The beam scanner 34 may further comprise optics (e.g. f-theta lens) to focus the laser beam 31 or sub-beams 33 onto the layer 2 of semiconductor material (e.g. amorphous silicon or IGZO).

The beam scanning arrangement may additionally or alternatively comprise a layer transport device 42 that moves the layer 2 of semiconductor material (e.g. amorphous silicon or IGZO), and thereby at least partially performs the scanning of the laser beam 31 or plurality of sub-beams 33 relative to the layer 2 of semiconductor material (e.g. amorphous silicon or IGZO).

The beam scanning arrangement may additionally or alternatively comprise an optics transport device 50, as shown for example in FIG. 3. The optics transport device 50 moves either or both of the laser source 30 and optics (or a portion of optics) for directing the laser beam 30 or plurality of sub-beams 33 onto the layer 2 of semiconductor material (e.g. amorphous silicon or IGZO), and thereby at least partially performs the scanning of the laser beam 31 or plurality of sub-beams 33 relative to the layer 2 of semiconductor material (e.g. amorphous silicon or IGZO). In the particular example of FIG. 3, the optics moved by the optics transport device 50 includes laser source 30, a beam shaping optical element 32′ (see below), a beam splitting optical element 32, and optics 52 (e.g. f-theta lens) to focus sub-beams 33 onto the layer 2 of semiconductor material (e.g. amorphous silicon or IGZO).

As depicted schematically in FIG. 4, in an embodiment each of the plurality of regions 8 of annealed semiconductor material (e.g. polysilicon or annealed IGZO) contains a region 6 in which a single electronic unit (e.g. TFT device) needed for a pixel of a display device (e.g. LCD or OLED display) will be provided. In an embodiment, the laser beam 31 or each sub-beam 33 is shaped by an optical element 32′ (see FIGS. 2 and 3) such as a diffractive optical element (DOE) to form a substantially rectangular spot 9 on the layer 2 of semiconductor material (e.g. amorphous silicon or IGZO). In an embodiment, each spot 9 is substantially the same size and shape as each of the plurality of regions 8. In an embodiment, each laser beam pulse has a substantially top-hat cross-sectional intensity profile. Thus, for the region 8 of FIG. 4, the intensity profile along line X-X′ would be as shown in FIG. 5. The intensity profile along line Y-Y′ would be as shown in FIG. 6. In an embodiment, the layer 2 of semiconductor material (e.g. amorphous silicon or IGZO) is positioned at the far field of a focussing lens. It is not necessary to form an accurate image at the layer 2 of semiconductor material because high spatial accuracy is not required. Regions of the semiconductor material (whether annealed or not) that are not needed to form part of the final manufactured device can be removed accurately using later processing techniques, such as optical lithography.

In contrast to prior art methods which convert substantially 100% of the amorphous silicon to polysilicon, at least in a region corresponding to a display region of a display to be manufactured, embodiments disclosed herein are configured to convert less than 20% of the layer of semiconductor material (e.g. amorphous silicon or IGZO) to annealed semiconductor material (e.g. polysilicon or annealed IGZO), optionally less than 10%, optionally less than 8%, optionally less than 6%, optionally less than 4%.

In an embodiment, each region 8 is slightly larger than the minimum size of the region 6 needed to create the electronic unit for each pixel (e.g. TFT device). For example, each region 8 may have a surface area equal to between 110% and 2000% of the surface area of the region 6 that it contains, optionally between 150% and 1000%, optionally between 200% and 800%, optionally between 300% and 600%. In one particular embodiment, for a region 6 for a TFT of 10×35 microns, regions 8 of 30×55 microns are provided.

In embodiments in which the laser beam 31 is split into a plurality of sub-beams 33, each sub-beam 33 may produce an individual spot 9 with each pulse of the laser beam 31. Each of the sub-beams 33 is focussed onto the layer 2 of semiconductor material (e.g. amorphous silicon or IGZO). Providing a plurality of sub-beams 33 makes it possible simultaneously to irradiate a plurality of regions 8 using a corresponding plurality of spots 9. The beam scanning arrangement (e.g. beam scanner 34) scans the sub-beams 33 over the layer 2 of semiconductor material (e.g. amorphous silicon or IGZO). In an embodiment the laser beam 31 is a pulsed laser beam and the scanning arrangement (e.g. beam scanner 34) is configured so that each sub-beam 33 is scanned relative to (over) the layer 2 of semiconductor material (e.g. amorphous silicon or IGZO) in such a way that successive pulses of the sub-beam 33 irradiate different respective ones of the plurality of regions 8 of the layer 2 of semiconductor material (e.g. amorphous silicon or IGZO) to be irradiated.

FIG. 7 depicts example trajectories 10 of a line of spots 9 across a portion of a layer 2 of semiconductor material (e.g. amorphous silicon or IGZO) (in the reference frame of the layer 2 of semiconductor material). The speed of scanning along the trajectories 10 and the pulse rate of the laser beam 31 are configured such that each sub-beam 33 generates a spot 9 of radiation at each point along the trajectory 10 corresponding to one of the regions 6 in which a TFT is to be formed, one spot being formed for each successive pulse of the laser beam 31. At a subsequent time, a different one of the sub-beams 33 follows the same trajectory 10 and provides a further spot 9 of radiation at each of the same points. The process is repeated until a plurality of regions 8, each containing one of the regions 6, is fully annealed, for example to form polysilicon or annealed IGZO. Thus, each of the plurality of regions 8 receives one pulse of radiation from each of two or more (different ones) of the sub-beams 33. In an embodiment, each of the plurality of regions 8 receives a single pulse (i.e. one and only one pulse) of radiation from each and every one of the sub-beams 33.

In an embodiment, the plurality of regions 8 to be irradiated comprises one or more sets of regions 8 (each containing a region 6) that are spaced apart from each other along a first direction with a first pitch 12. In the example of FIG. 7, the first direction is the vertical direction within the page, and each set of regions 8 comprises a vertically aligned column of regions 8. A plurality of the sets of regions 8 (columns) are provided, each set of regions 8 being aligned with a corresponding set of the regions 6 (so that each region 8 contains one of the regions 6). The plurality of sub-beams 33 comprises at least one set of sub-beams 33 that are spaced apart from each other in the first direction with the same first pitch 12 at the layer 2 of semiconductor material (e.g. amorphous silicon or IGZO), thereby producing a corresponding set of spots 9 that are spaced apart from each other in the first direction with the same first pitch 12 (as shown in FIG. 7). This enables multiple sub-beams 33 to simultaneously irradiate multiple corresponding regions 8 (each region 8 lying on a different one of the horizontal trajectories 10). The plurality of sub-beams 33 in each set of sub-beams are aligned with each other along the first direction.

In the example of FIG. 7 the plurality of sub-beams 33 comprises only one of the abovementioned sets of sub-beams 33 (aligned along the first direction). In other embodiments further such sets of sub-beams 33 may be provided that are separated from each other in a perpendicular direction to form a two-dimensional array of sub-beams 33. An example is discussed below with reference to FIG. 10. In an embodiment each of the plurality of regions 8 receives a single pulse of radiation from each of the sub-beams 33 in at least one of the abovementioned sets of sub-beams 33.

In an embodiment, the beam scanning arrangement moves the layer of semiconductor material (e.g. amorphous silicon or IGZO) in the first direction during the scanning of the sub-beams 33 relative to the layer 2 of semiconductor material (e.g. amorphous silicon or IGZO), for example along the trajectories 10 of FIG. 7. In an embodiment, the layer 2 of semiconductor material (e.g. amorphous silicon or IGZO) is moved relative to a beam scanner 34 along the first direction and the beam scanner 34 scans the sub-beams 33 (and therefore spots 9) in a direction that is oblique relative to the first direction in order to compensate for the movement of the layer 2 of semiconductor material (e.g. amorphous silicon or IGZO). In FIG. 7 the trajectories 10 are shown in the reference frame of the layer 2 of semiconductor material (e.g. amorphous silicon or IGZO). In the reference frame of the beam scanner 34 each trajectory 10 would move diagonally (i.e. at an oblique angle relative to the vertical) upwards so as to follow the upwards motion of each of the regions 6 and position the spot 9 over a respective region 6 each time the laser beam 31 pulses.

In an embodiment, each region 8 receives a single pulse (i.e. one and only one pulse) of radiation from each and every one of the sub-beams 33 of radiation in at least one of the abovementioned sets of sub-beams (i.e. from each and every one of the sub-beams 33 when only one of the sets of sub-beams 33 is provided). Thus, where each region 8 needs to receive N pulses of radiation, N sub-beams 33 will be provided in each set of sub-beams 33. In an embodiment, N=20, but other values of N may be used.

A bow-tie type scanning arrangement, an example of which is depicted in FIG. 8, may be used to efficiently move the set of sub-beams 33 across the surface of the layer 2 of semiconductor material (e.g. amorphous silicon or IGZO). For example, in a scan involving movement of each sub-beam 33 (and associated spot 9) along the trajectory from point 21 to point 22, a set of N sub-beams 33 is scanned along N lines of regions 8 (each region 8 containing one of the TFT regions 6). At point 22 each sub-beam 33 (and associated spot 9) is moved down to point 23, which corresponds to a distance equivalent to the first pitch 12, and is then scanned along the trajectory from point 23 to point 24 to irradiate another N lines of regions 8 (overlapping with the previous N lines of regions). Each sub-beam 33 (and associated spot) is then moved back to point 21, which corresponds again to a distance equivalent the first pitch 12, ready for scanning a further N lines of regions 8. The process continues in this embodiment until all of the regions 8 on the layer 2 of semiconductor material (e.g. amorphous silicon or IGZO) have been irradiated by N successive laser pulses to form the annealed semiconductor material (e.g. polysilicon or annealed IGZO) in each of the regions 8.

In the scanning process described above with reference to FIGS. 7 and 8, the beam scanning arrangement provides a raster scan in the reference frame of the layer 2 of semiconductor material (e.g. amorphous silicon or IGZO) of a beam spot 9 from each of a set of sub-beams 33 aligned along the first direction over all of the plurality of regions 8 to be irradiated. Thus, each and every one of the set of sub-beams 33 is scanned over each and every one of the regions 8 to be irradiated. The scanning path 46 is illustrated schematically (in the reference frame of the layer 2 of semiconductor material to be annealed) in FIG. 9. The set of sub-beams 33 aligned along the first direction produces a corresponding set 44 of beams spots 9. The first direction 48 is vertically upwards in the plane of the page. The long axis of the raster scan is perpendicular to the first direction 48 (horizontal in the plane of the page).

In an embodiment, the plurality of sub-beams 33 comprises a plurality of the sets of sub-beams 33 aligned along the first direction (producing a corresponding plurality of sets 44 of beam spots 9). Each of the sets 44 is separated from each other set 44 in a direction perpendicular to the first direction by a second pitch. A two-dimensional array of sub-beams 33 is thereby formed, defined by the first pitch and the second pitch. The two-dimensional array of sub-beams 33 produces a corresponding two-dimensional array of beam spots 9 (illustrated schematically in the upper left portion of FIG. 10). In an embodiment each set comprises N sub-beams 33 as described above (but other values of N may be used). The number M of sets is not particularly limited. Optionally M is larger than N, optionally larger than 20, optionally larger than 30, optionally larger than 40.

FIG. 10 depicts an example scanning path 46 for an embodiment comprising an M×N array of sub-beams producing an M×N array of beam spots 9. The scanning path comprises a raster scan in the reference frame of the layer 2 of semiconductor material (e.g. amorphous silicon or IGZO) of the array of sub-beams 33 (and beam spots 9) over the layer 2 of semiconductor material (e.g. amorphous silicon or IGZO). In embodiments of this type a long axis of the raster scan may be parallel to the first direction 48 (vertical in the example of FIG. 10). Embodiments of this type may be implemented by a beam scanning arrangement which does not use a beam scanner 34. In other words, the scanning is achieved without using deflection or steering of the laser beam to provide the scanning. Instead, the scanning is provided by moving either or both of 1) the layer 2 of semiconductor material (e.g. amorphous silicon or IGZO), and 2) the laser source 30 and optics (or a portion of optics) for directing the laser beam 30 or plurality of sub-beams 33 onto the layer 2 of semiconductor material (e.g. amorphous silicon or IGZO). In the example shown in FIG. 10, for example, the scanning may be implemented by using a layer transport device to move the layer 2 of semiconductor material (e.g. amorphous silicon or IGZO) along each of the vertical portions of the scanning path 46 while holding the sub-beams 33 stationary (by holding the laser source 30 and/or associated optics stationary). An optics transport device may then be used to step the laser source and/or associated optics in the horizontal direction to move the sub-beams 33 and thereby provide each of the horizontal portions of the scanning path 46. Alternatively all of the scanning path 46 could be provided solely by movement of the layer 2 of semiconductor material (e.g. amorphous silicon or IGZO) (i.e. in a two-dimensional scan) or all of the scanning path 46 could be provided solely by movement of the laser source 30 and/or associated optics.

In an embodiment, all of the sub-beams 33 have the same intensity and the energy per pulse delivered to each sub-region 8 is therefore constant (each pulse delivers the same energy to the region 8). This is illustrated schematically by the bar chart in FIG. 11 showing the variation of energy density received at a region 8 as a function of time (in the case where each region receives a pulse from 25 different sub-beams 33).

FIG. 12 depicts an alternative embodiment in which the sub-beams 33 have progressively increasing intensities, such that the energy per pulse delivered to each sub-region 8 progressively increases as a function of time (each pulse delivers a higher energy per pulse than the preceding pulse). The intensity of each sub-beam 33 remains constant during the scanning. The progressive increase in energy per pulse received by each region 8 is provided by the differences in intensity between different sub-beams 33, which can in turn be controlled by suitable design of the diffractive optical element. An example in which the energy per pulse progressively (monotonically) increases is illustrated by the bar chart in FIG. 12. Other arrangements are possible. Any variation which encourages efficient (e.g. using a low total amount of laser energy) and/or high quality (e.g. providing a quality of polysilicon that is particularly well adapted for forming reliable and long-lived electronic devices and/or which achieves high uniformity across the different regions 8) can be envisaged.

A progressively increasing energy density arrangement such as that shown in FIG. 12 is desirable compared to a constant arrangement such as shown in FIG. 11 since it leads to a more gradual annealing and, where applicable, crystallization of the semiconductor material (e.g. amorphous silicon or IGZO) and hence a reduction in the likelihood of film disruption.

FIG. 13 depicts an example in which the variation in energy pulse is configured to imitate the variation that is intrinsic to prior art approaches using scanning of a line laser beam, i.e. an approximate Gaussian variation. This approach allows the method to produce annealed semiconductor material (e.g. polysilicon or annealed IGZO) of a quality corresponding to prior art approaches

A progressively increasing energy density arrangement such as that shown in FIG. 12 is also desirable compared to a rising and falling arrangement such as shown in FIG. 13 since all of the successively increasing energy density pulses contribute fully to the progressive annealing and, where applicable, crystallization of the semiconductor material (e.g. amorphous silicon or IGZO) whereas pulses with reducing energy density as occur after the peak in FIG. 13 make significantly less contribution to the annealing and, where applicable, crystallization process.

In the arrangements discussed above, each of the regions 8 receives plural pulses of radiation (e.g. one from each of the sub-beams 33 provided). In an alternative embodiment the apparatus 1 is configured such that each of the plurality of regions 8 receives a single pulse of radiation from the radiation beam. The single pulse of radiation converts the semiconductor material (e.g. amorphous silicon or IGZO) to annealed semiconductor material (e.g. polysilicon or annealed IGZO) without any further pulses being required. Optionally, an optical element 32 is provided to split the laser beam into a plurality of sub-beams. In this case the scanning of the laser beam comprises scanning of the sub-beams and the single pulse of radiation received by each of the plurality of regions 8 is received from one of the sub-beams. Providing plural sub-beams may speed up processing of the layer 2 of semiconductor material in comparison to where only one radiation beam spot can be incident on the layer 2 at any one time.

FIG. 14 depicts schematically how the apparatus 1 can be scaled up to process larger layers 2 of semiconductor material (e.g. amorphous silicon or IGZO), for example for larger displays, or multiple laterally adjacent layers 2 of semiconductor material (e.g. for multiple displays), as shown in the FIG. 14. In the example configuration shown, the apparatus 1 comprises a gantry comprising a plurality of laser sources 30 (ten in the particular example shown). Each source 30 provides radiation simultaneously to two optical systems 36 (such that 20 optical systems 36 are provided). Each optical system 36 comprises an optical element 32 configured to split a laser beam 31 into a plurality of sub-beams 33, an optical element 32′ to shape the sub-beams 33, and a corresponding beam scanner 34 (including focussing optics such as an f-theta lens). The beam scanner 34 scans the sub-beams 33 over a layer 2 of semiconductor material (e.g. amorphous silicon or IGZO). In the configuration shown the layers 2 of semiconductor material (e.g. amorphous silicon or IGZO) will be moved vertically downwards (as depicted in the page) underneath the gantry while the sub-beams 33 are scanned substantially left and right (e.g. in a bow-tie type pattern as described above).

In an embodiment, further steps of a method of manufacturing a display are performed after processing the layer 2 of semiconductor material (e.g. amorphous silicon or IGZO) to produce the regions 8 of polysilicon. In an embodiment, an electronic device such as a TFT for driving a pixel of a display, is formed in each of the regions 8. In an embodiment a flat panel display such as an LCD or OLED display is manufactured that includes the electronic devices.

Embodiments of the disclosure are also described by the following numbered clauses.

1. An apparatus for annealing a layer of amorphous silicon, comprising:

a laser source configured to generate a laser beam; and

a beam scanner configured to scan the laser beam in such a way as to selectively irradiate a plurality of regions of the layer of amorphous silicon and thereby generate a corresponding plurality of regions of polysilicon by annealing, wherein each of the regions of polysilicon is separated from all of the other regions of polysilicon.

2. The apparatus of clause 1, further comprising an optical element configured to split the laser beam into a plurality of sub-beams, wherein the scanning of the laser beam comprises scanning of the sub-beams.
3. The apparatus of clause 2, wherein the laser beam is a pulsed laser beam and the beam scanner is configured so that each sub-beam is scanned over the layer of amorphous silicon in such a way that successive pulses of the sub-beam irradiate different respective ones of the plurality of regions of the layer of amorphous silicon to be irradiated.
4. The apparatus of clause 2 or 3, wherein the plurality of regions to be irradiated are spaced apart from each other with a pitch and the sub-beams generated by the optical element are spaced apart from each other with the same pitch.
5. The apparatus of any of clauses 2-4, configured to move the layer of amorphous silicon relative to the beam scanner during the irradiation of the plurality of regions.
6. The apparatus of clause 5, wherein:

the layer of amorphous silicon is moved relative to the beam scanner along a first direction; and

the sub-beams generated by the optical element are aligned parallel to the first direction and the beam scanner is configured to scan the sub-beams in a direction that is oblique relative to the first direction in order to compensate for the movement of the layer of amorphous silicon.

7. The apparatus of any of clauses 2-6, configured such that each of the plurality of regions receives one pulse of radiation from each of at least two of the sub-beams.
8. The apparatus of clause 7, configured such that each of the plurality of regions receives a single pulse of radiation from each of the sub-beams.
9. The apparatus of any of clauses 2-8, wherein the laser source is a pulsed laser source and the apparatus is configured such that the energy per pulse received by each of the plurality of regions is substantially the same for each pulse.
10. The apparatus of any of clauses 2-8, wherein the laser source is a pulsed laser source and the apparatus is configured such that the energy per pulse received by each of the plurality of regions is substantially different for at least two of the pulses received by the region.
11. The apparatus of clause 10, wherein the energy per pulse received by each of the plurality of regions increases progressively for each pulse received by the region.
12. The apparatus of any of clauses 2-11, wherein each sub-beam of radiation has a substantially top-hat cross-sectional intensity profile.
13. The apparatus of any preceding clause, configured to convert less than 20% of the layer of amorphous silicon to polysilicon.
14. The apparatus of any preceding clause, configured such that each of the plurality of regions receives a single pulse of radiation from the laser beam.
15. The apparatus of clause 14, further comprising an optical element configured to split the laser beam into a plurality of sub-beams, wherein the scanning of the laser beam comprises scanning of the sub-beams, and the single pulse of radiation received by each of the plurality of regions is received from one of the sub-beams.
16. A method of annealing a layer of amorphous silicon, comprising:

generating a laser beam; and

scanning the laser beam over the layer of amorphous silicon in such a way as to selectively irradiate a plurality of regions of the layer of amorphous silicon and thereby generate a corresponding plurality of regions of polysilicon, wherein each of the regions of polysilicon is separated from all of the other regions of polysilicon.

17. The method of clause 16, wherein the selective irradiation is performed by splitting the laser beam into a plurality of sub-beams and scanning the sub-beams over the layer of amorphous silicon.
18. The method of clause 17, wherein the laser beam is a pulsed laser beam and each sub-beam is scanned over the layer of amorphous silicon in such a way that successive pulses of the sub-beam irradiate different respective ones of the plurality of regions of the layer of amorphous silicon to be irradiated.
19. The method of clause 17 or 18, wherein the sub-beams are spaced apart from each other with the same pitch as the plurality of regions to be irradiated.
20. The method of any of clauses 17-19, wherein the layer of amorphous silicon is moved during the irradiation of the plurality of regions.
21. The method of clause 20, wherein:

the layer of amorphous silicon is moved along a first direction during the irradiation of the plurality of regions; and

the sub-beams are aligned parallel to the first direction and scanned in a direction that is oblique relative to the first direction in order to compensate for the movement of the layer of amorphous silicon.

22. The method of any of clauses 17-21, wherein each of the plurality of regions receives one pulse of radiation from each of at least two of the sub-beams.
23. The method of claim 22, wherein each of the plurality of regions receives a single pulse of radiation from each of the sub-beams.
24. The method of any of clauses 17-23, wherein each sub-beam of radiation has a substantially top-hat cross-sectional intensity profile.
25. The method of any of clauses 16-22, wherein the laser beam is pulsed and the energy per pulse received by each of the plurality of regions is substantially the same for each pulse.
26. The method of any of clauses 16-24, wherein the laser beam is pulsed and the energy per pulse received by each of the plurality of regions is substantially different for at least two of the pulses received by the region.
27. The method of clause 26, wherein the energy per pulse received by each of the plurality of regions increases progressively for each pulse received by the region.
28. The method of any of clauses 16-27, wherein less than 20% of the layer of amorphous silicon is converted to polysilicon.
29. The method of any of clauses claims 16-28, wherein each of the plurality of regions receives a single pulse of radiation from the laser beam.
30. The apparatus of clause 29, further comprising an optical element configured to split the laser beam into a plurality of sub-beams, wherein the scanning of the laser beam comprises scanning of the sub-beams, and the single pulse of radiation received by each of the plurality of regions is received from one of the sub-beams.
31. The method of any of clauses 16-30, further comprising manufacturing an electronic device in each of the regions of polysilicon.
32. The method of clause 31, wherein each region of polysilicon has a surface area at least 10% larger than the surface area of the region occupied by the electronic device in each region.
33. The method of clause 32, wherein each electronic device comprises a thin film transistor.
34. The method of any of clauses 16-33, further comprising manufacturing a flat panel display using the regions of polysilicon.
35. A flat panel display manufactured using the method of any of clauses 16-34.

1. An apparatus for annealing a layer of semiconductor material, comprising:
a laser source configured to generate a laser beam; and
a beam scanning arrangement configured to scan a plurality of sub-beams generated from the laser beam, relative to the layer of semiconductor material in such a way as to selectively irradiate a plurality of regions of the layer of semiconductor material and thereby generate a corresponding plurality of regions of annealed semiconductor material by annealing, wherein each of the regions of annealed semiconductor material is separated from all of the other regions of annealed semiconductor material wherein the laser beam is a pulsed laser beam and the beam scanning arrangement is configured so that each sub-beam of the plurality of sub-beams is scanned relative to the layer of semiconductor material in such a way that successive pulses of the sub-beam irradiate different respective ones of the plurality of regions of the layer of semiconductor material to be irradiated.

2. (canceled)

3. The apparatus of claim 1, configured such that each of the plurality of regions receives one pulse of radiation from each of at least two different sub-beams.

4. The apparatus of claim 1, wherein the laser source is a pulsed laser source and the apparatus is configured such that the energy per pulse received by each of the plurality of regions is substantially the same for each pulse.

5. The apparatus of claim 1, wherein the laser source is a pulsed laser source and the apparatus is configured such that the energy per pulse received by each of the plurality of regions is substantially different for at least two of the pulses received by the region.

6. The apparatus of claim 5, wherein the energy per pulse received by each of the plurality of regions increases progressively for each pulse received by the region.

7. The apparatus of claim 1, wherein:
the plurality of regions to be irradiated comprises at least one set of regions that are spaced apart from each other along a first direction with a first pitch; and
the plurality of sub-beams comprises at least one set of sub-beams that are spaced apart from each other in the first direction with the first pitch, at the layer of semiconductor material.

8. The apparatus of claim 7, configured such that each of the plurality of regions receives a single pulse of radiation from each of the sub-beams in at least one of said sets of sub-beams.

9. The apparatus of claim 8, wherein the sub-beams in each of said sets of sub-beams are aligned with each other along the first direction, at the layer of semiconductor material.

10. The apparatus of claim 7, wherein the beam scanning arrangement moves the layer of semiconductor material in the first direction during the scanning of the sub-beams relative to the layer of semiconductor material.

11. The apparatus of claim 10, wherein the beam scanning arrangement provides a raster scan in the reference frame of the layer of semiconductor material of each beam spot from each of at least one of said sets of sub-beams over all of the plurality of regions to be irradiated.

12. The apparatus of claim 11, wherein a long axis of the raster scan is perpendicular to the first direction in the reference frame of the layer of semiconductor material.

13. The apparatus of claim 7, wherein the plurality of sub-beams comprises a plurality of said sets of sub-beams, each set being separated from each other set in a direction perpendicular to the first direction by a second pitch, at the layer of semiconductor material, thereby forming a two-dimensional array of sub-beams defined by the first pitch and the second pitch.

14. The apparatus of claim 13, wherein the beam scanning arrangement provides a raster scan in the reference frame of the layer of semiconductor material of beams spots from the two-dimensional array of sub-beams over the layer of semiconductor material.

15. The apparatus of claim 14, wherein a long axis of the raster scan is parallel to the first direction.

16. The apparatus of claim 1, wherein the beam scanning arrangement comprises a beam scanner configured to provide movement relative to the laser source of one or more beam spots generated by the laser beam or by the plurality of sub-beams, and thereby at least partially perform the scanning of the laser beam or plurality of sub-beams relative to the layer of semiconductor material.

17. The apparatus of claim 1, wherein the beam scanning arrangement comprises a layer transport device configured to move the layer of semiconductor material, and thereby at least partially perform the scanning of the laser beam or plurality of sub-beams relative to the layer of semiconductor material.

18. The apparatus of claim 1, wherein the beam scanning arrangement comprises an optics transport device configured to move either or both of the laser source and optics for directing the laser beam or plurality of sub-beams onto the layer of semiconductor material, and thereby at least partially perform the scanning of the laser beam or plurality of sub-beams relative to the layer of semiconductor material.

19. The apparatus of claim 1, further comprising an optical element configured to generate the plurality of sub-beams by splitting the laser beam.

20. The apparatus of claim 1, wherein each sub-beam of radiation has a substantially top-hat cross-sectional intensity profile.

21. The apparatus of claim 1, configured to convert less than 20% of the layer of semiconductor material to annealed semiconductor material.

22. The apparatus of claim 1, configured such that each of the plurality of regions receives a single pulse of radiation from the laser beam.

23. The apparatus of claim 22, further comprising an optical element configured to split the laser beam into a plurality of sub-beams, wherein the scanning of the laser beam comprises scanning of the sub-beams, and the single pulse of radiation received by each of the plurality of regions is received from one of the sub-beams.

24. The apparatus of claim 1, wherein the semiconductor material comprises amorphous silicon prior to the annealing and the annealed semiconductor material comprises polysilicon.

25. The apparatus of claim 1, wherein the semiconductor material comprises indium gallium zinc oxide prior to the annealing and the annealed semiconductor material comprises annealed indium gallium zinc oxide.

26. A method of annealing a layer of semiconductor material, comprising:
generating a laser beam; and
scanning a plurality of sub-beams generated from the laser beam, over the layer of semiconductor material in such a way as to selectively irradiate a plurality of regions of the layer of semiconductor material and thereby generate a corresponding plurality of regions of annealed semiconductor material, wherein each of the regions of annealed semiconductor material is separated from all of the other regions of annealed semiconductor material wherein the laser beam is a pulsed laser beam and each sub-beam is scanned over the layer of semiconductor material in such a way that successive pulses of the sub-beam irradiate different respective ones of the plurality of regions of the layer of semiconductor material to be irradiated.

27-39. (canceled)

40. The method of claim 26, further comprising manufacturing an electronic device in each of the regions of annealed semiconductor material.

41. The method of claim 40, wherein each region of annealed semiconductor material has a surface area at least 10% larger than the surface area of the region occupied by the electronic device in each region.

42. The method of claim 40, wherein each electronic device comprises a thin film transistor.

43. The method of claim 26, further comprising manufacturing a flat panel display using the regions of annealed semiconductor material.

44-45. (canceled)

46. A flat panel display manufactured using the method of claim 26.
